(19) United States
(12) Patent Application Publication
(10) Pub. No.: US 2026/0182442 A1
(43) Pub. Date: Jun. 25, 2026

(54) SEMICONDUCTOR PACKAGE

(71) Applicant: Taiwan Semiconductor Manufacturing Company, LTD., Hsinchu (TW)

(72) Inventors: Chih-Hang Chang, Taoyuan (TW); Pei-Chun Liao, Jubei (TW); Huei-Wen Yang, Hsinchu (TW)

(21) Appl. No.: 18/991,970

(22) Filed: Dec. 23, 2024

(51) Int. Cl. H01L 23/31; H01L 21/56; H01L 23/00; H01L 23/20; H01L 23/29; H01L 25/07

(52) U.S. Cl. CPC H10W 74/124; H10W 74/01; H10W 74/127; H10W 74/43; H10W 76/43; H10W 80/312; H10W 80/327; H10W 90/00; H10W 90/26; H10W 90/792

(57) ABSTRACT

Methods for forming a semiconductor package are disclosed. A gap fill layer with a recess is formed on a first semiconductor die. A second semiconductor die is placed in the recess. A gap remains between the second semiconductor die and the gap fill layer. The first semiconductor die and the second semiconductor die are bonded together. A sealant layer is formed that fills an upper region of the gap. The lower region of the gap serves as an air gap, and is not filled with a solid material. Semiconductor packages so formed are also disclosed, as well as using such packages for various applications.

### BACKGROUND

Integrated circuits are formed on a semiconductor wafer. Photolithographic patterning processes use ultraviolet light to transfer a desired mask pattern to a photoresist on a semiconductor wafer. Etching processes may then be used to transfer to the pattern to a layer below the photoresist. This process is repeated multiple times with different patterns to build different layers on the wafer substrate and make a useful device.

Semiconductor packages containing integrated circuits are becoming increasingly complex. For example, System on Integrated Chip (SoIC) has been developed to include a plurality of device dies such as processors and memory cubes which are stacked vertically and interconnected. The device dies can be formed using different technologies and have different functions, and can be heterogeneously combined to obtain desired functionality, thus forming a system which is combined in one chip carrier package. This reduces manufacturing costs and optimizes device performance. Similar three-dimensional packages include System in Package (SiP), Wafer Level Package (WLP), and Package on Package (PoP), among others.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a Y-axis cross-sectional view of a semiconductor package, in accordance with some embodiments. A gap is present around the second (top) semiconductor die, and a seal layer bridges the gap between the gap fill layer and the second semiconductor die. FIG. 1B is a plan view showing the second semiconductor die, the seal layer, and the gap fill layer.

FIG. 2 is a flow chart illustrating a first method for forming a semiconductor package, in accordance with some embodiments.

FIG. 3 is a cross-sectional view showing a first semiconductor die and a second semiconductor die.

FIG. 4A is a cross-sectional view showing the first semiconductor die after a gap fill layer including a recess has been formed thereon. FIG. 4B is a plan view.

FIG. 5 is a cross-sectional view showing the second semiconductor die being placed into the recess.

FIG. 6 is a cross-sectional view showing the first semiconductor die after bonding to the second semiconductor die. A gap between the second semiconductor die and the gap fill layer is also shown.

FIG. 7 is a cross-sectional view after the sealant layer has been formed in an upper region of the gap.

FIG. 8 is a cross-sectional view after a fusion bonding layer has been formed over the second semiconductor die.

FIG. 9 is a cross-sectional view after a carrier wafer is applied to the semiconductor package.

FIG. 10 is a cross-sectional view showing the semiconductor package after application of a second interconnect layer on a back side of the first semiconductor die.

FIG. 11 is a flow chart illustrating a second method for forming a semiconductor package, in accordance with some embodiments.

FIG. 12 is a cross-sectional view showing the first semiconductor die after a first gap fill layer including a first recess has been formed thereon.

FIG. 13 is a cross-sectional view after the second semiconductor die has been inserted into the first recess and bonded to the first semiconductor die. A gap between the second semiconductor die and the gap fill layer is also shown.

FIG. 14 is a cross-sectional view after a first sealant layer has been formed, and a primary interconnect layer has been formed over the second semiconductor die.

FIG. 15 is a cross-sectional view after a second gap fill layer including a second recess has been formed over the primary interconnect layer, and a third semiconductor die has been inserted into the second recess and bonded to the primary interconnect layer.

FIG. 16 is a cross-sectional view after a second sealant layer has been formed, and a secondary interconnect layer has been formed over the third semiconductor die.

FIG. 17 is a flow chart illustrating a third method for forming a semiconductor package, in accordance with some embodiments.

FIG. 18 is a cross-sectional view showing a gap fill layer with a recess formed on a first semiconductor die, and also showing an intermediate package formed by bonding a second semiconductor die and a third semiconductor die together.

FIG. 19 is a cross-sectional view after the intermediate package has been inserted into the recess, and the second semiconductor die has been bonded to the first semiconductor die.

FIG. 20 is a cross-sectional view after a sealant layer has been formed to seal the gap.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Numerical values in the specification and claims of this application should be understood to include numerical values which are the same when reduced to the same number of significant figures and numerical values which differ from the stated value by less than the experimental error of conventional measurement technique of the type described in the present application to determine the value. All ranges disclosed herein are inclusive of the recited endpoint.

The term “about” can be used to include any numerical value that can vary without changing the basic function of that value. When used with a range, “about” also discloses the range defined by the absolute values of the two endpoints, e.g. “about 2 to about 4” also discloses the range “from 2 to 4.” The term “about” may refer to plus or minus 10% of the indicated number.

The present disclosure relates to systems and devices which are made up of multiple components and/or different layers. When the terms “on” or “upon” or “over” are used with reference to two different components or layers, they indicate merely that one component/layer is on or upon or over the other component/layer. These terms do not require the two components/layers to directly contact each other, and permit other components/layers to be between them. The term “directly” may be used to indicate two components/layers directly contact each other without any other components/layers in between them. In addition, when referring to performing process steps to a component/substrate, this should be construed as performing such steps to whatever layers may be present on the component/substrate as well, depending on the context.

The term “semiconductor package”, as used in the present disclosure, refers to the combination of two or more integrated circuits (also referred to as a die, chip, or microchip) through interconnect layers that permits the integrated circuits to communicate with each other. Typically, each die or chip includes an interconnect layer on one or both sides of the integrated circuit substrate. Examples of an interconnect layer may include a redistribution layer (RDL) or an interposer having bond pads or C4 bumps or pillars. The resulting semiconductor package may also have an interconnect layer on only one side, or on both sides, as will be seen further herein. It is noted that in the art, the term “package” is used to refer to many different structures and does not have a single fixed definition.

The present disclosure relates to methods for resolving crack issues that can occur on semiconductor packages, such as Chip-on-Wafer (CoW). The top chip is bonded to the bottom wafer to form a semiconductor package, a gap fill material is subsequently deposited over the package. Etching and/or planarization may be performed to remove the gap fill material that is upon the top chip. However, due to the deposition process, cracks can easily form along the sidewall of the top chip. The gap fill layer is mechanically weak along the sidewall, and also has high residual stress at the bottom of the sidewall. The present disclosure provides methods which reduce or eliminate these crack issues, and also have reduced mechanical stress.

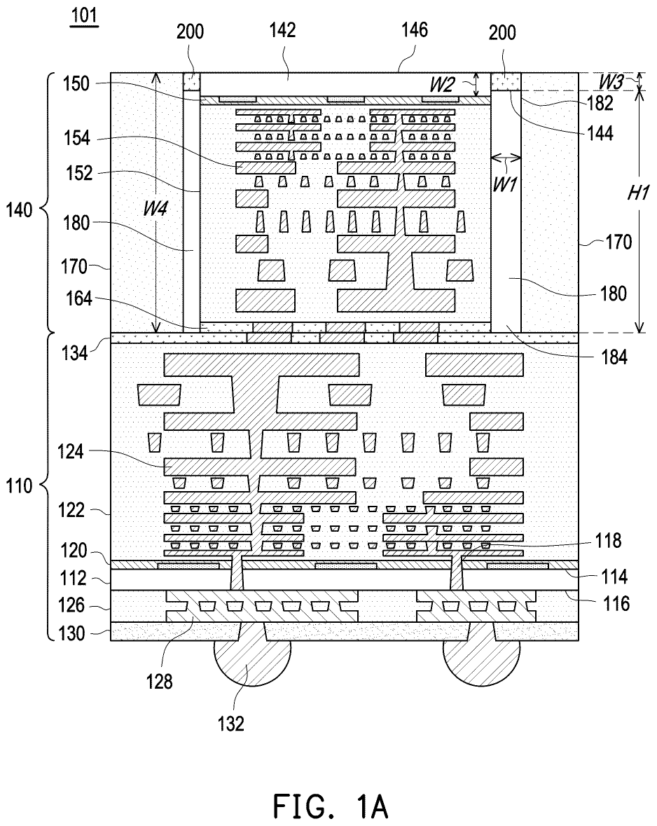

FIG. 1A is a cross-sectional view of one example of a semiconductor package 101, in accordance with some embodiments of the present disclosure. FIG. 1B is a plan view. The semiconductor package 101 includes a first or bottom semiconductor die 110, and a second or top semiconductor die 140 which are bonded together. A gap fill layer 170 surrounds the second semiconductor die 140.

The first semiconductor die 110 includes a substrate 112 that has a front side 114 and a back side 116. The substrate is a wafer made of a semiconducting material in certain embodiments. Such semiconductor materials can include silicon, for example in the form of crystalline Si. In alternative embodiments, the substrate can be made of other elementary semiconductors such as germanium, or may include a compound semiconductor such as silicon carbide (SiC), gallium arsenide (GaAs), gallium carbide, gallium phosphide, indium arsenide (InAs), indium phosphide (InP), silicon germanium, silicon germanium carbide, gallium arsenic phosphide, or gallium indium phosphide. In particular embodiments, the wafer substrate is silicon.

Continuing, multiple layers are formed upon the substrate which together make up an integrated circuit, shown here as one layer 120. Integrated circuits are built up from different patterns of electrically conductive materials and electrically insulating materials to make useful components. Suitable examples of integrated circuit components may include, for example and without limitation, active components (e.g., transistors), passive components (e.g., capacitors, inductors, resistors, and the like), or combinations thereof. These components may be made from electrically conductive materials such as metals like copper, aluminum, gold, tungsten, iron, ruthenium, iridium, and alloys thereof. Suitable examples of electrically insulating materials (i.e. dielectric materials) may include oxides such as silicon dioxide (SiO₂), aluminum oxide (Al₂O₃), tantalum oxide (Ta₂O₅), zirconium dioxide (ZrO₂), or hafnium dioxide (HfO₂); nitrides such as silicon carbon nitride (SiCN), silicon nitride (SiN), hafnium oxynitride (HfOₓN_{y}), zirconium oxynitride (ZrOₓN_{y}), or silicon oxynitride (SiOₓN_{y}), where 0<x, y, ≤1; silicates like hafnium silicates (HfSiₓO_{y}) or zirconium silicates (ZrSiₓO_{y}), where 0<x, y, ≤1; polysilicon, phosphosilicate glass (PSG), fluorosilicate glass (FSG), undoped silicate glass (USG), high-stress undoped silicate glass (HSUSG), borosilicate glass (BSG), a high-k dielectric material, or a low-k dielectric material.

Continuing, a first interconnect layer 122 is present upon the front side 114 of the substrate over the integrated circuit layer 120. A second interconnect layer 126 is also present upon the back side 116 of the substrate. Each interconnect layer may be formed from multiple interconnect or dielectric sublayers and etch stop sublayers. The interconnect sublayers may independently be considered intermetal dielectric (IMD) layers or interlayer dielectric (ILD) layers. Metal routing 124, 128 is illustrated as being present within each interconnect layer 122, 126. Through-silicon vias 118 are also illustrated which pass through the substrate and provide electrical connections between the first interconnect layer 122 and the second interconnect layer 126. In addition, a buffer layer 130 is illustrated upon the second interconnect layer 126. Electrical connectors 132 are also present on the back side. The connectors are illustrated as bumps, but may be lands, balls, pins, pillars, or other similar structures. Finally, a hybrid bonding layer 134 is present on the front side of the substrate, over the first interconnect layer 122.

The second or top semiconductor die 140 generally has the same structure as the first semiconductor die. This includes a substrate 142 that has a front side 144 and a back side 146, an integrated circuit layer 150, a first interconnect layer 152 containing metal routing 154, and a hybrid bonding layer 164. These individual layers have the same general structure as described above with respect to the first semiconductor die 110. It is noted that the two hybrid bonding layers 134, 164 are adjacent to each other.

A gap 180 is present between the second semiconductor die 140 and the gap fill layer 170. A sealant layer 200 fills the space between the second semiconductor die and the gap fill layer. As seen in FIG. 1B, the gap and the sealant layer 200 extend around all sides of the second semiconductor die 140. The gap 180 has a top 182 and a bottom 184 (the bottom being proximate the first semiconductor die). The gap may be filled with any appropriate gas, such as air or an inert gas like nitrogen or argon.

Referring back to FIG. 1A, the width of the gap is indicated as W1. The height or thickness of the silicon substrate of the second semiconductor die is indicated as W2. It is noted that here, the gaps on both sides of the second semiconductor die are drawn as being equal (or in other words the second semiconductor die is centered), but this is not required, and W1 is the average of the width of the two sides. In particular embodiments, W1 is less than or equal to 1.5*W2. In further embodiments, W1 is less than or equal to W2. For example, W2 may range from about 5 micrometers to about 20 micrometers. However, other values and ranges for each of these measurements are also within the scope of this disclosure. If W1 is much larger, it becomes difficult to seal the gap at the top and the sealant material instead falls to the bottom of the gap.

Continuing, the height or thickness of the sealant layer 200 is indicated as W3, and the height of the second semiconductor die 140 and the gap fill layer 170 (which are substantially the same) is indicated as W4. In particular embodiments, W3 is less than or equal to 0.5*W4. This is believed to be sufficient to seal the top of the gap and maintain structural integrity. In additional embodiments, W3 is at least 5 micrometers. In some particular embodiments, W4 is from about 10 micrometers to about 15 micrometers. The height of the gap between the first semiconductor die 110 and the sealant layer 200 is indicated as H1, and is usually at least 5 micrometers. However, other values and ranges for each of these measurements are also within the scope of this disclosure.

The gap fill layer 170 has an O/Si molar ratio, and the sealant layer 200 also has an O/Si molar ratio. In particular embodiments, the O/Si molar ratio of the gap fill layer is greater than the O/Si molar ratio of the sealant layer. In some embodiments, the O/Si molar ratio of both layers may be between the ranges of about 1.7 to about 2.3. in addition, the O/Si molar ratio of both layers between their top and bottom desirably varies by less than 1. However, other values and ranges for each of these measurements are also within the scope of this disclosure.

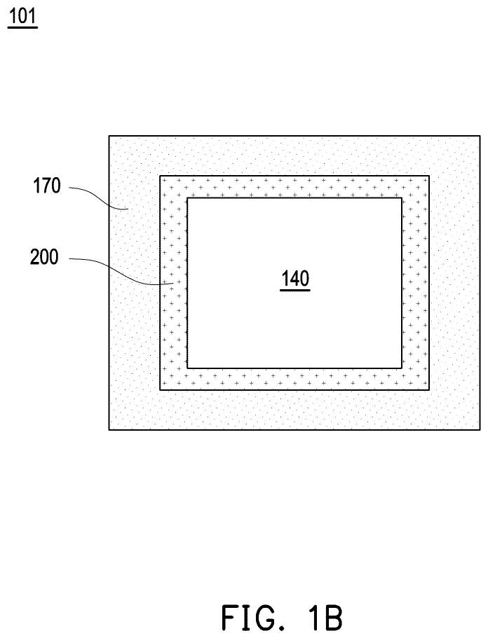

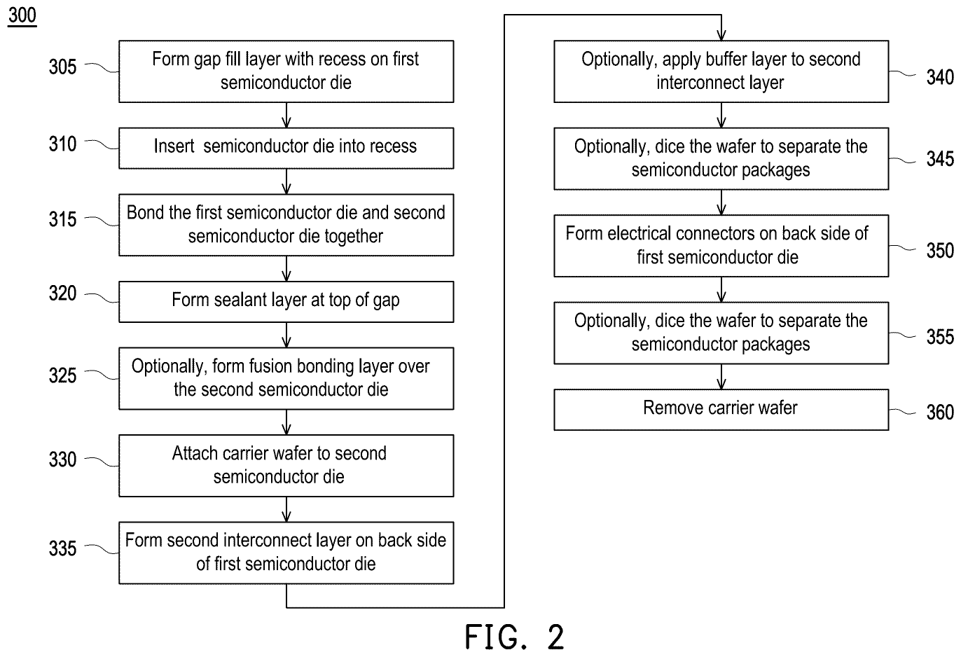

FIG. 2 is a flow chart illustrating a first method 300 for making a semiconductor package 101, in accordance with some embodiments. Some steps of the method are also illustrated in FIGS. 3-10, which are Y-axis cross-sectional views. These figures provide different views for better understanding. While the method steps are discussed below in terms of forming a single semiconductor package, such discussion should also be broadly construed as applying to the formation of multiple semiconductor packages concurrently. It is noted that not all steps described in the flow chart are required, and not all method steps are described in the flow chart.

In this method, the semiconductor package 101 is formed from two separate dies or chips. Initially, FIG. 3 shows the first semiconductor die 110 and the second semiconductor die 140 separately. The first semiconductor die 110 includes the substrate 112, integrated circuit layer 120, first interconnect layer 122, through-silicon vias 118, and hybrid bonding layer 134. The second semiconductor die 140 includes the substrate 142, integrated circuit layer 150, first interconnect layer 152, and hybrid bonding layer 164. The first interconnect layer 122, 152 is formed on the front side 114, 144 of each substrate 112, 142. It is contemplated that in some embodiments, the first semiconductor die 110 is part of a larger wafer that has not yet been diced and separated.

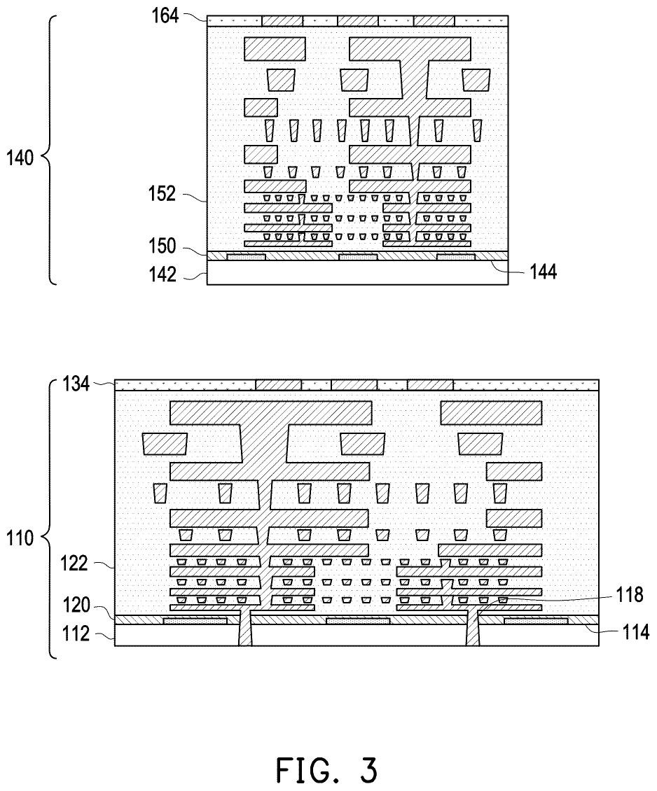

In step 305 of FIG. 2 and as illustrated in FIG. 4A and FIG. 4B, a gap fill layer 170 is formed on the front side 114 of the first semiconductor die 110. The gap fill layer is formed from a dielectric material. In particular embodiments, the gap fill layer is formed from an oxide, such as silicon dioxide (SiO₂). However, any suitable material may be used. The gap fill layer may be formed by appropriate patterning and deposition, such as by chemical vapor deposition (CVD), physical vapor deposition (PVD), atomic layer deposition (ALD), or other suitable methods. As better seen in the plan view of FIG. 4B, the gap fill layer includes a recess 204, through which the fusion bonding layer 134 of the first semiconductor die is visible.

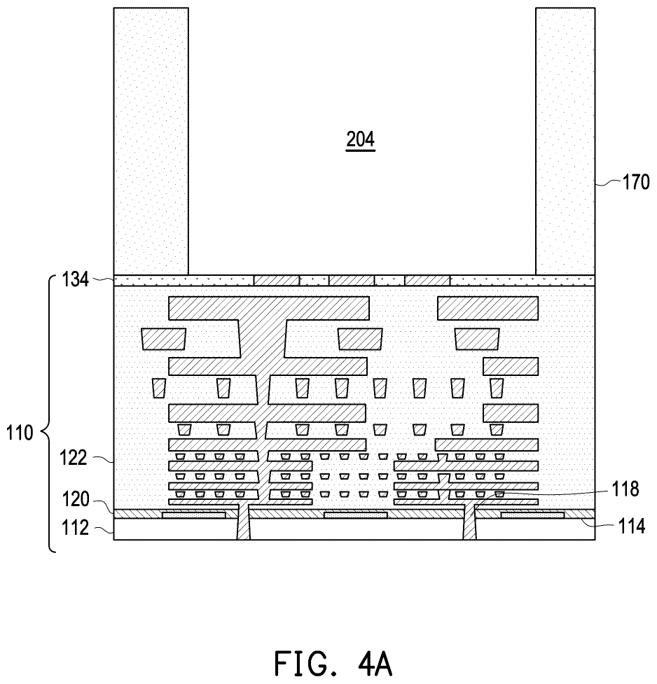

Next, in step 310 of FIG. 2 and as illustrated in FIG. 5, the second semiconductor die 140 is placed or inserted into the recess 204. It is noted that the second semiconductor die 140 is flipped over, so the two hybrid bonding layers 134, 164 will contact each other.

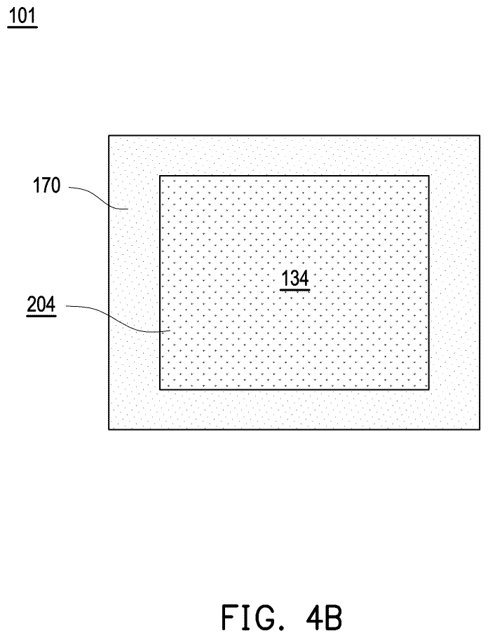

As seen in FIG. 6, a gap 180 remains between the second semiconductor die 140 and the gap fill layer 170. The gap is indicated as having width W1 and height H2. The gap also includes an upper region 186 and a lower region 188. Continuing, in step 315 of FIG. 2, the first semiconductor die 110 and the second semiconductor die 140 are bonded together. Hybrid bonding refers to the use of both a dielectric bond and a metal bond to form an interconnection between two dies. Each hybrid bonding layer 134, 164 includes a dielectric material and a plurality of metal bond pads. The dielectric material on each die is activated (usually by plasma) to be hydrophilic. When the metal bond pads of the two dies are aligned and the dielectric layers of the two dies are brought together, the dielectric layers bond together, referred to herein as a hybrid bond layer. The two-die system is then annealed to cause the metal bond pads to bond together and expand and fill any gaps. Electrical connections may also be formed between the two dies, for passing electrical signals between them.

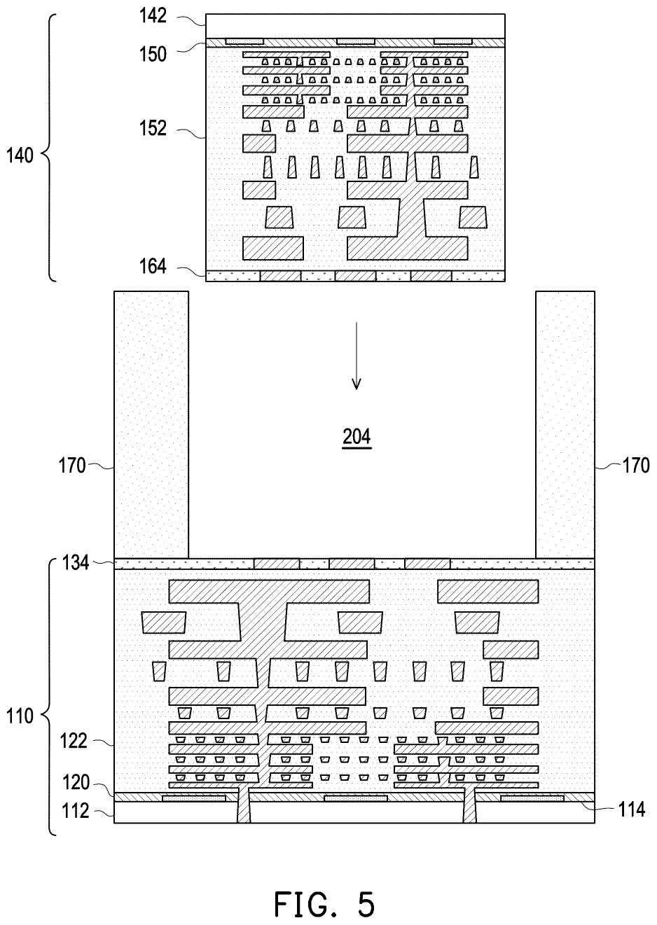

Then, in step 320 of FIG. 2 and as illustrated in FIG. 7, a sealant layer 200 is formed. The sealant layer 200 fills the upper region 186 of the gap 180, such that the height of the gap is reduced from H2 to H1. The sealant layer is formed from a dielectric material. In particular embodiments, the sealant layer is formed from silicon dioxide (SiO₂), silicon nitride (Si₃N₄), or silicon carbide (SiC). However, any suitable material may be used. In particular, the sealant layer 200 and the gap fill layer 170 can be made from the same or different materials.

The sealant layer may be formed by any suitable method, and in particular embodiments is formed by plasma-enhanced CVD (PE-CVD). After the sealant layer is applied, the volume below the sealant layer is still considered a gap, and is not filled with a solid material. It is noted that the atmosphere within the gap 180 is determined by the atmosphere during these processing steps, which can be controlled as desired. The sealant layer 200 is illustrated here as filling the upper region 186 and also forming a layer over the gap fill layer. In some embodiments, the portion over the gap fill layer can be removed by planarization.

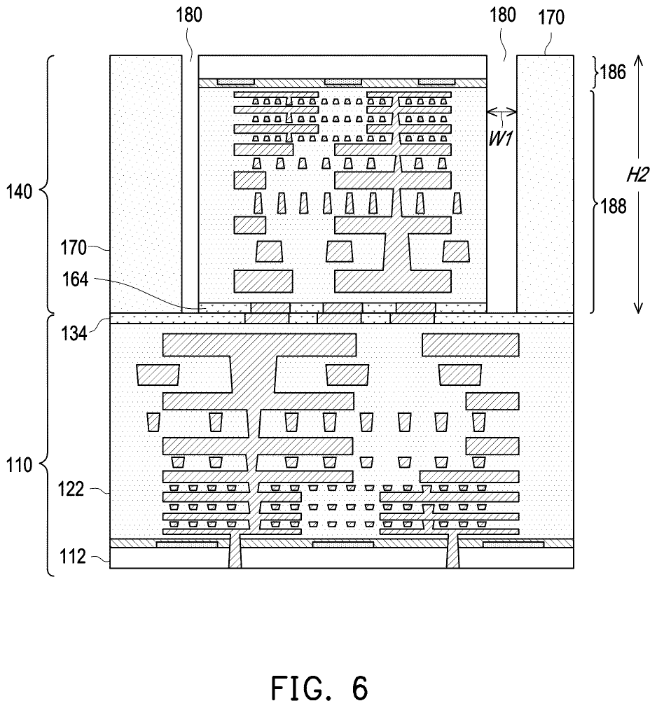

Next, in optional step 325 of FIG. 2 and as illustrated in FIG. 8, a fusion bonding layer 208 is formed over the second semiconductor die 140. The fusion bonding layer is formed from a dielectric material. In particular embodiments, the fusion bonding layer layer is formed from silicon dioxide (SiO₂), silicon nitride (Si₃N₄), or silicon carbide (SiC).; silicon oxynitride (SiOxN_{y}), or silicon hydroxide (SiOH). However, any suitable material may be used. The fusion bonding layer may be formed by any suitable method. In alternative embodiments, the portion of the sealant layer 200 shown in FIG. 7 can be planarized and then used as the fusion bonding layer.

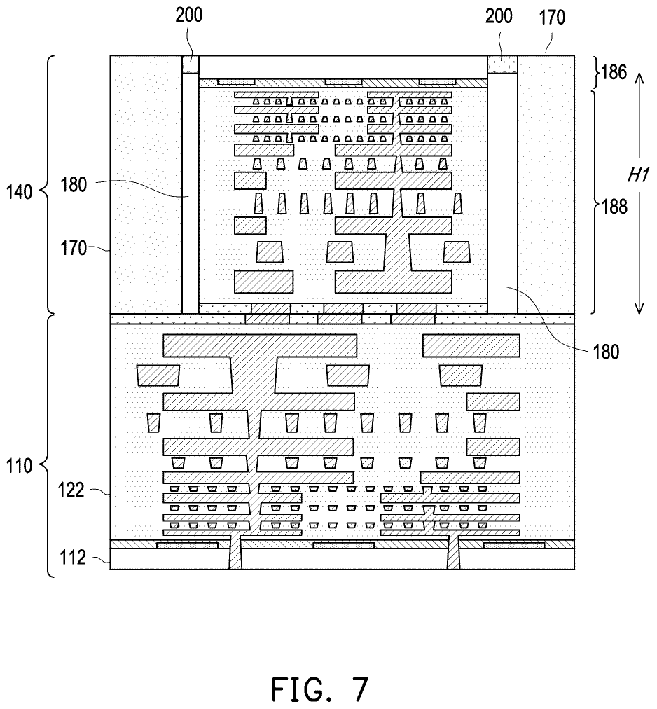

Then, in step 330 of FIG. 2 and as illustrated in FIG. 9, a carrier wafer 210 is attached to the second semiconductor die, for example through the fusion bonding layer 208. This permits the semiconductor package to be flipped over for additional processing on the back side of the first semiconductor die 110.

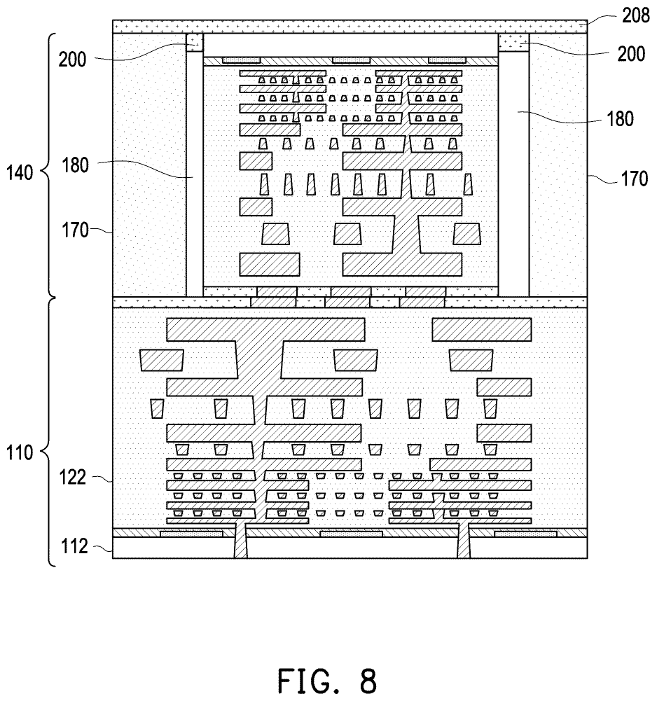

In step 335 of FIG. 2 and as illustrated in FIG. 10, a second or back side interconnect layer 126 is formed on the first semiconductor die 110. The second interconnect layer 126 includes metal routing 128, and is electrically connected to the through-silicon vias 118. In optional step 340 of FIG. 2, a buffer layer 130 may be applied to the second interconnect layer 126. The buffer layer may be, for example, formed from a polyimide. The buffer layer is then etched. Then, in step 350 of FIG. 2, electrical connectors 132 are formed which are electrically connected to the second interconnect layer 126. In step 360 of FIG. 2, the carrier wafer 210 is removed. The resulting semiconductor package is shown in FIG. 1A and FIG. 1B.

As previously mentioned, in some embodiments, the first semiconductor die 110 is part of a larger wafer, and the second semiconductor die is thus attached to the larger water. Thus, an optional dicing step may also be performed to separate the semiconductor package that has not yet been diced and separated. This optional dicing step may be performed as step 345, i.e. prior to the formation of the electrical connectors 132, or as step 355, i.e. prior to removing the carrier wafer.

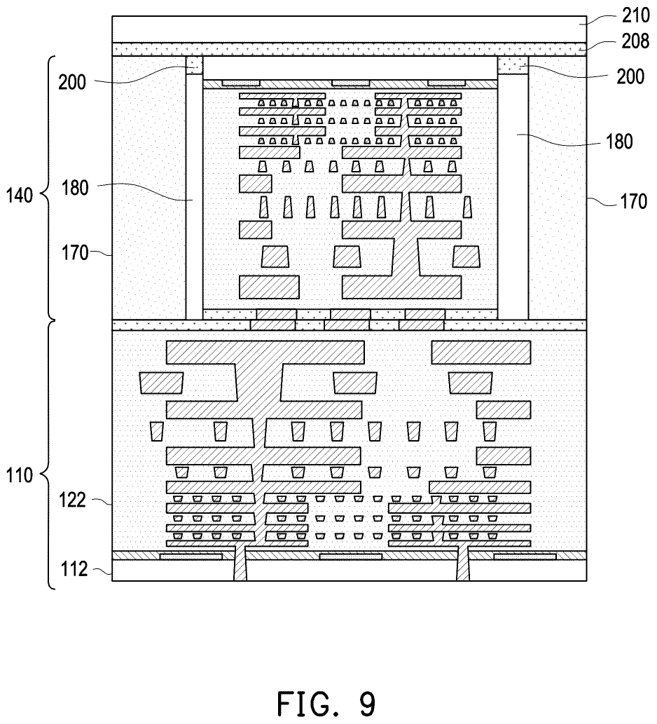

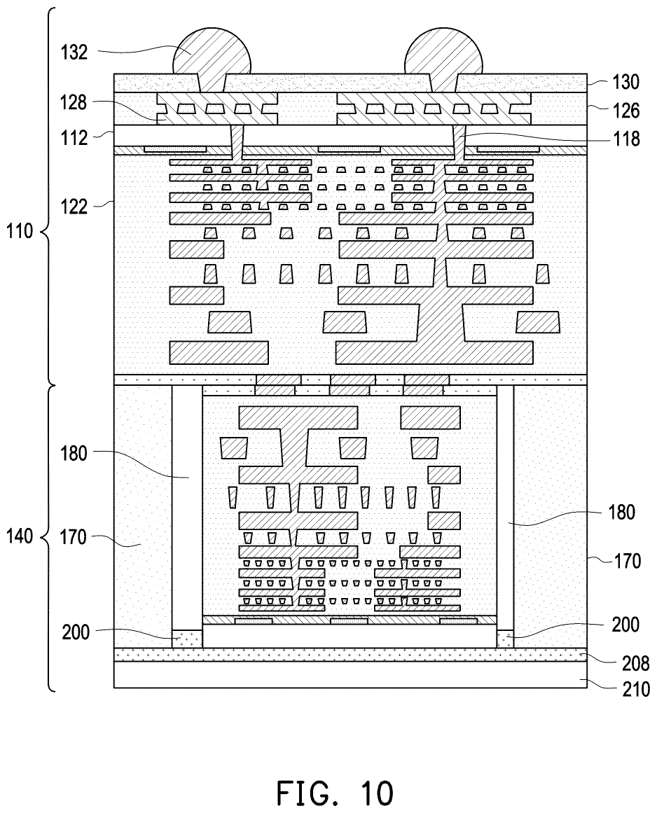

FIG. 11 is a flow chart illustrating another method 400 for making a semiconductor package 102, in accordance with some embodiments. Some steps of the method are also illustrated in FIGS. 12-16, which are Y-axis cross-sectional views. Again, this discussion should also be broadly construed. Again, not all steps described in the flow chart are required, and not all method steps are described in the flow chart.

In this method, the semiconductor package 102 is formed from three separate dies or chips. In step 405 of FIG. 11 and as illustrated in FIG. 12, a first gap fill layer 170 is formed on a first semiconductor die 110. The first semiconductor die is illustratively represented here as having a substrate 112 and a first interconnect layer 122. The first gap fill layer 170 is formed upon the first interconnect layer 122. The first gap fill layer 170 includes a first recess 204.

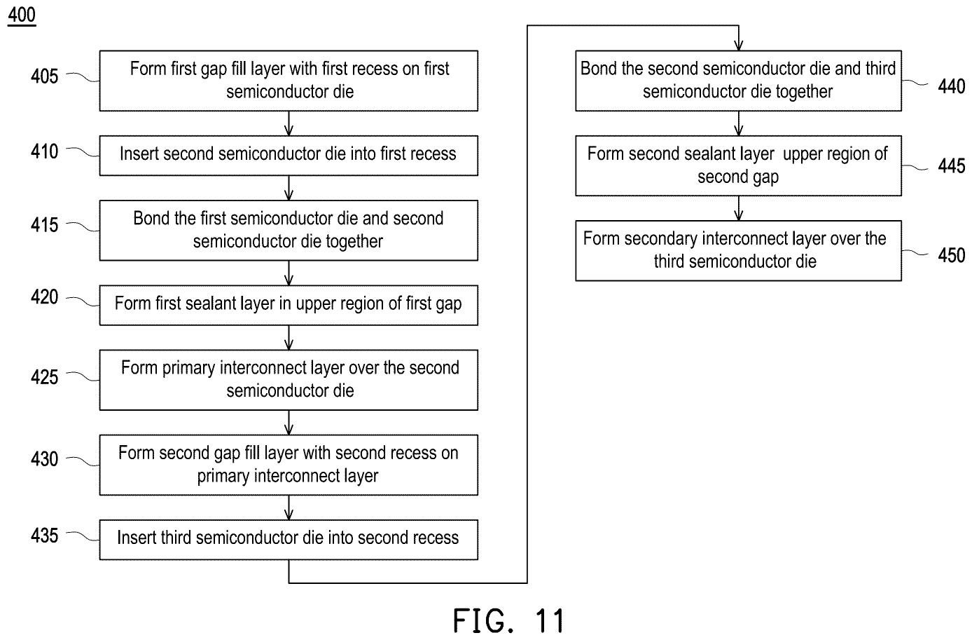

In step 410 of FIG. 11 and as illustrated in FIG. 13, a second semiconductor die 140 is placed or inserted into the first recess. The second semiconductor die is also illustratively represented here as having a substrate 142 and a first interconnect layer 152. A first gap 180 remains between the second semiconductor die 140 and the first gap fill layer 170. Then, in step 415 of FIG. 11, the first semiconductor die 110 and the second semiconductor die 140 are bonded together. This may be done, for example, by hybrid bonding.

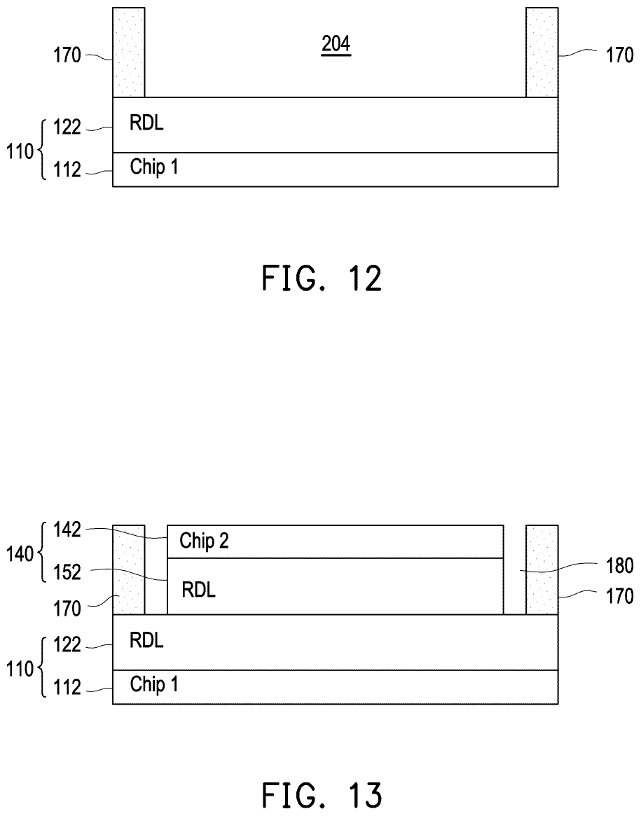

Next, in step 420 of FIG. 11 and as illustrated in FIG. 14, a first sealant layer 200 is formed, which fills an upper region of the first gap 180. Depending on the amount of sealant applied, planarization to remove excess sealant may then be performed. Then, in step 425 of FIG. 11, a primary interconnect layer 212 is formed over the second semiconductor die 140. As illustrated here, the primary interconnect layer 212 also extends over the first sealant layer 200 and the first gap fill layer 170. The primary interconnect layer may include metal routing (not shown) over the second semiconductor die and simply be dielectric material over the first sealant layer 200 and the first gap fill layer 170.

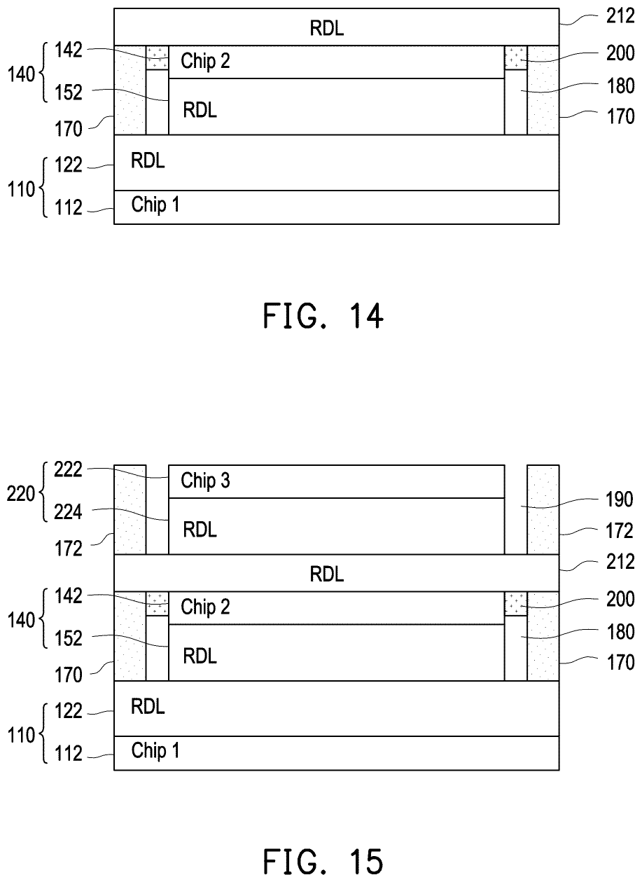

In step 430 of FIG. 11 and as illustrated in FIG. 15, a second gap fill layer 172 is formed on the primary interconnect layer 212. The second gap fill layer 172 includes a second recess (not shown). Next, in step 435 of FIG. 11, a third semiconductor die 220 is placed or inserted into the second recess. The third semiconductor die is also illustratively represented here as having a substrate 222 and a first interconnect layer 224. A second gap 190 remains between the third semiconductor die 220 and the second gap fill layer 172. Then, in step 440 of FIG. 11, the third semiconductor die 220 and the primary interconnect layer 212 are bonded together. This may be done, for example, by hybrid bonding (where a hybrid bonding layer is present on each interconnect layer). If the primary interconnect layer is considered part of the second semiconductor die, then this step can also be considered as bonding the second semiconductor die and the third semiconductor die together.

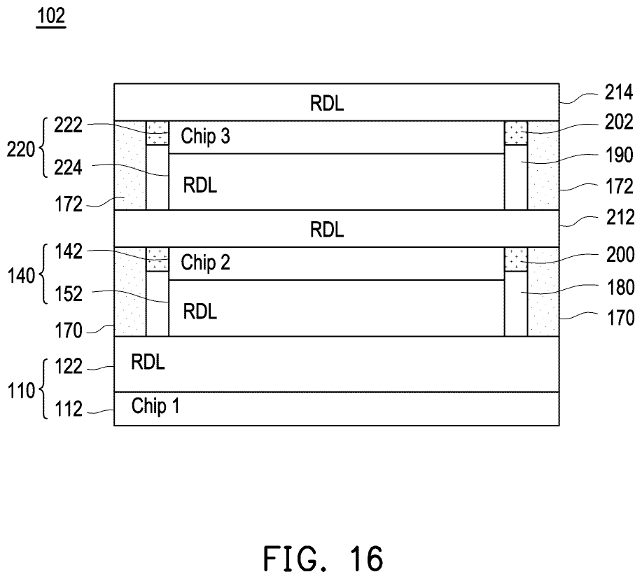

Next, in step 445 of FIG. 11 and as illustrated in FIG. 16, a second sealant layer 202 is formed, which fills an upper region of the second gap 190. Depending on the amount of sealant applied, planarization to remove excess sealant may then be performed. Then, in step 450 of FIG. 11, a secondary interconnect layer 214 is formed over the third semiconductor die 220. As illustrated here, the secondary interconnect layer 214 also extends over the second sealant layer 202 and the second gap fill layer 172. Steps 430-450 of this method could be repeated to permit the stacking of any number of dies together.

Although not illustrated, steps 325-360 of FIG. 2 may also be performed after step 450 of FIG. 11 (with appropriate modification in consideration of the third semiconductor die). These steps result in the formation of another interconnect layer on the backside of the first semiconductor die. Again, if the first semiconductor die 110 is part of a larger wafer, dicing may also be performed as described in FIG. 2.

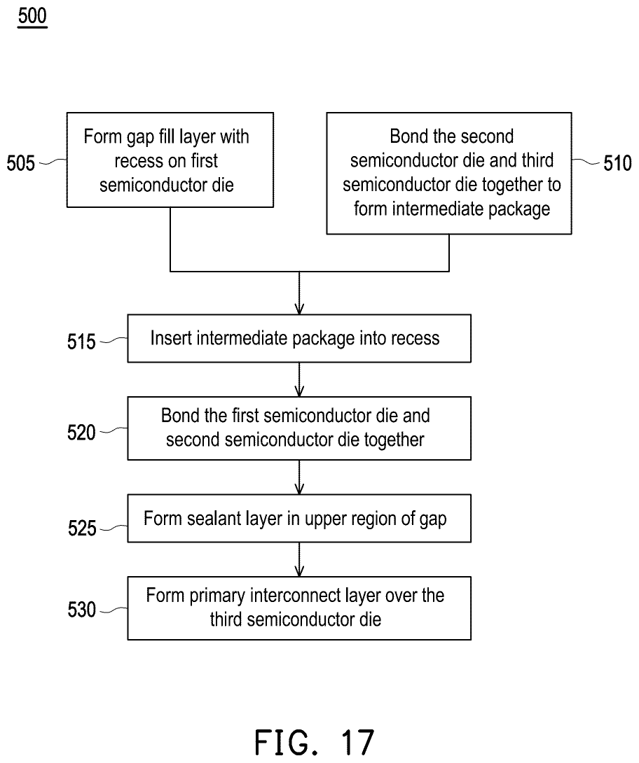

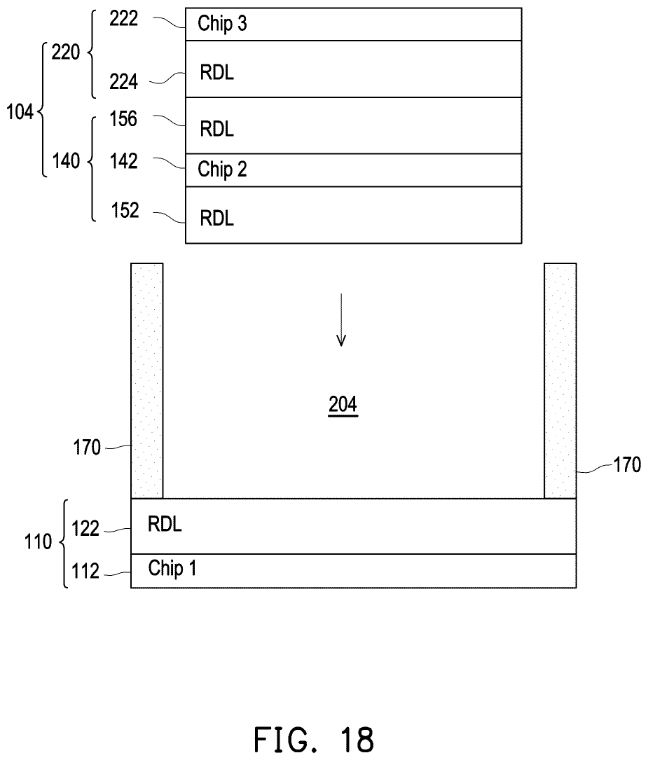

FIG. 17 is a flow chart illustrating another method 500 for making a semiconductor package 103, in accordance with some embodiments. Some steps of the method are also illustrated in FIGS. 18-20, which are Y-axis cross-sectional views. Again, this discussion should also be broadly construed. Again, not all steps described in the flow chart are required, and not all method steps are described in the flow chart.

In this method, the semiconductor package 103 is also formed from three separate dies or chips, but the process steps are carried out in a different order. In step 505 of FIG. 17 and as illustrated in FIG. 18, a gap fill layer 170 is formed on the first semiconductor die 110. The first semiconductor die is illustratively represented here as having a substrate 112 and a first interconnect layer 122. The gap fill layer 170 is formed upon the first interconnect layer 122. The gap fill layer 170 includes a recess 204.

Continuing, the second semiconductor die 140 is illustratively represented here as having a substrate 142, a first interconnect layer 152 on one side of the substrate, and a second interconnect layer 156 on the other side of the substrate. However, the second interconnect layer 156 may not be required. The third semiconductor die 220 is also illustratively represented as having a substrate 222 and a first interconnect layer 224. In step 510 of FIG. 17, the second semiconductor die 140 and the third semiconductor die 220 are bonded together to form an intermediate package 104. This may be done, for example, by hybrid bonding. As labeled here, the second interconnect layer 156 of the second semiconductor die 140 is bonded to the first interconnect layer 122 of the third semiconductor die 220. It is noted that these steps can take place in either order, as indicated in FIG. 17. It is also noted that step 510 could be repeated to permit the stacking of any number of dies together.

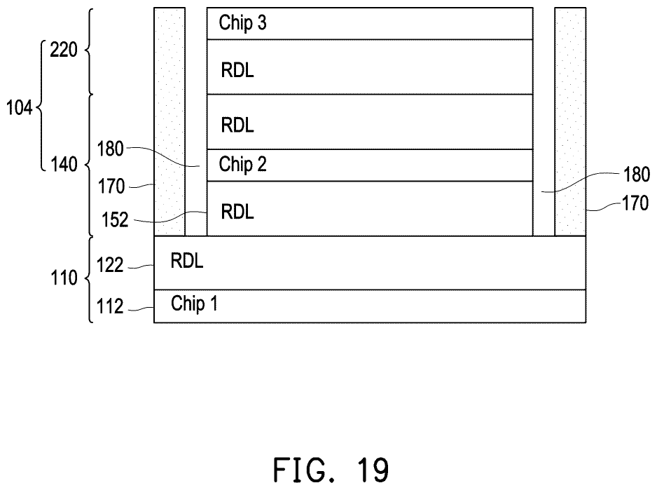

In step 515 of FIG. 17 and as illustrated in FIG. 19, the intermediate package 104 is placed or inserted into the recess 204. It is noted the recess has a sufficient depth to accommodate the intermediate package. The intermediate package is placed in the recess such that the first semiconductor die 110 is proximate the second semiconductor die 140. A gap 180 remains between the intermediate package 104 and the gap fill layer 170. Then, in step 520 of FIG. 17, the first semiconductor die 110 and the second semiconductor die 140 are bonded together. This may be done, for example, by hybrid bonding. As labeled here, the first interconnect layer 122 of the first semiconductor die 110 is bonded to the first interconnect layer 152 of the second semiconductor die 140.

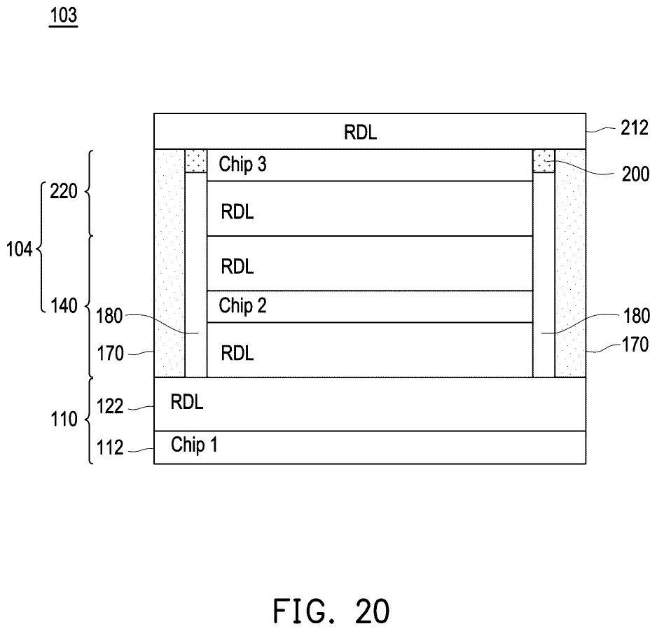

Next, in step 525 of FIG. 17 and as illustrated in FIG. 20, a sealant layer 200 is formed, which fills an upper region of the gap 180. In step 530 of FIG. 17, a primary interconnect layer 212 may be formed over the third semiconductor die 220, which could also extend over the sealant layer 200 and the gap fill layer 170.

Although not illustrated, steps 325-360 of FIG. 2 may also be performed after step 530 of FIG. 17 (with appropriate modification in consideration of the third semiconductor die). These steps result in the formation of another interconnect layer on the backside of the first semiconductor die. Again, if the first semiconductor die 110 is part of a larger wafer, dicing may also be performed as described in FIG. 2.

It is noted that certain detailed steps are not expressly described in the discussion above. For example, a pattern/structure may be formed in a given layer by applying a photoresist layer, patterning the photoresist layer, developing the photoresist layer, and then etching.

Generally, a photoresist layer may be applied, for example, by spin coating, or by spraying, roller coating, dip coating, or extrusion coating. Typically, in spin coating, the substrate is placed on a rotating platen, which may include a vacuum chuck that holds the substrate in plate. The photoresist composition is then applied to the center of the substrate. The speed of the rotating platen is then increased to spread the photoresist evenly from the center of the substrate to the perimeter of the substrate. The rotating speed of the platen is then fixed, which can control the thickness of the final photoresist layer.

Next, the photoresist composition is baked or cured to remove the solvent and harden the photoresist layer. In some particular embodiments, the baking occurs at a temperature of about 90° C. to about 110° C. The baking can be performed using a hot plate or oven, or similar equipment. As a result, the photoresist layer is formed on the substrate.

The photoresist layer is then patterned via exposure to radiation. The radiation may be any light wavelength which carries a desired mask pattern. In particular embodiments, EUV light having a wavelength of about 13.5 nm is used for patterning, as this permits smaller feature sizes to be obtained. This results in some portions of the photoresist layer being exposed to radiation, and some portions of the photoresist not being exposed to radiation. This exposure causes some portions of the photoresist to become soluble in the developer and other portions of the photoresist to remain insoluble in the developer.

An additional photoresist bake step (post exposure bake, or PEB) may occur after the exposure to radiation. For example, this may help in releasing acid leaving groups (ALGs) or other molecules that are significant in chemical amplification photoresist.

The photoresist layer is then developed using a developer. The developer may be an aqueous solution or an organic solution. The soluble portions of the photoresist layer are dissolved and washed away during the development step, leaving behind a photoresist pattern. One example of a common developer is aqueous tetramethylammonium hydroxide (TMAH). Generally, any suitable developer may be used. Sometimes, a post develop bake or “hard bake” may be performed to stabilize the photoresist pattern after development, for optimum performance in subsequent steps.

Continuing, portions of the layer below the patterned photoresist layer are now exposed. Etching transfers the photoresist pattern to the layer below the patterned photoresist layer. After use, the patterned photoresist layer can be removed, for example, using various solvents such as N-methyl-pyrrolidone (NMP) or alkaline media or other strippers at elevated temperatures, or by dry etching using oxygen plasma.

Generally, any etching step used herein may be performed using wet etching, dry etching, or plasma etching processes such as reactive ion etching (RIE) or inductively coupled plasma (ICP), or combinations thereof, as appropriate. The etching may be anisotropic. Depending on the material, etchants may include carbon tetrafluoride (CF₄), hexafluoroethane (C₂F₆), octafluoropropane (C₃F₈), fluoroform (CHF₃), difluoromethane (CH₂F₂), fluoromethane (CH₃F), carbon fluorides, nitrogen (N₂), hydrogen (H₂), oxygen (O₂), argon (Ar), xenon (Xe), xenon difluoride (XeF₂), helium (He), carbon monoxide (CO), carbon dioxide (CO₂), fluorine (F₂), chlorine (Cl₂), hydrogen bromide (HBr), hydrofluoric acid (HF), nitrogen trifluoride (NF₃), sulfur hexafluoride (SF₆), boron trichloride (BCl₃), ammonia (NH₃), bromine (Br₂), nitrogen trifluoride (NF₃), or the like, or combinations thereof in various ratios. For example, silicon dioxide can be wet etched using hydrofluoric acid and ammonium fluoride. Alternatively, silicon dioxide can be dry etched using various mixtures of CHF₃, O₂, CF₄, and/or H₂.

Planarization of a surface may be performed, for example, using a chemical mechanical polishing (CMP) process. Generally, CMP is performed using a rotating platen to which a polishing pad is attached. The substrate is attached to a rotating carrier. A slurry or solution containing various chemicals and abrasives is dispensed onto the polishing pad or the wafer substrate. During polishing, both the polishing pad and the carrier rotate, and this induces mechanical and chemical effects on the surface of the wafer substrate and/or the top layer thereon, removing undesired materials and creating a highly level surface. A post-CMP cleaning step is then carried out using rotating scrubber brushes along with a washing fluid to clean one or both sides of the wafer substrate.

Finally, cleaning steps such as wet cleaning may be performed between various processing steps. The cleaning solution will depend on the etch recipe and the exposed layers. Examples of cleaning solutions may include deionized water, dilute HF, and other conventional solutions.

The semiconductor packages may be used in various devices useful for different applications. Non-limiting examples of such devices may include, for example, image signal processors (ISP), which can be combined with CMOS image sensors; or global shutters for high speed capture in a camera or monitor. Other potential applications might include BCD (Bipolar-CMOS-DMOS) circuits for driving discrete high voltage components; drivers for LCD, OLED, AMOLED, or QLED display panels; image sensors that can be used in systems such as mobile telephones, facial recognition systems, or as motion sensors for automotive applications, security applications, energy efficiency, etc. ; power management devices that control the flow and direction of electrical power; and/or artificial intelligence applications.

The methods and resulting semiconductor packages described herein have several advantages. Stress is reduced at both the top and the bottom of the gap due to the use of the sealant layer to seal the gap, rather than filling the entire gap. In addition, operational costs are reduced due to the use of less gap fill material (none applied upon the top semiconductor die, which must be removed). The process time for certain processing steps, such as CMP, is also reduced due to the lack of gap fill material upon the top semiconductor die. The sealant layer also has greater mechanical strength and thus higher resistance to cracking compared to the process where gap fill material is applied upon the top semiconductor die and then removed.

The present disclosure thus relates in some embodiments to various methods forming a semiconductor package. A gap fill layer is formed on a first semiconductor die. The gap fill layer includes a recess. A second semiconductor die is placed in the recess. A gap remains between the second semiconductor die and the gap fill layer. The first semiconductor die and the second semiconductor die are bonded together. A sealant layer is formed that fills an upper region of the gap.

Also disclosed herein are semiconductor packages comprising a first semiconductor die. A second semiconductor die is bonded to the first semiconductor die. A gap fill layer surrounds the second semiconductor die, with a gap remaining around the second semiconductor die. A sealant layer is located around the second semiconductor die that seals the gap. In some further embodiments, the package further comprises a primary interconnect layer that extends over the second semiconductor die, the sealant layer, and the gap fill layer.

Also disclosed herein are additional methods for forming a semiconductor package. A first gap fill layer is formed on a first semiconductor die. The first gap fill layer includes a first recess. A second semiconductor die is placed in the first recess, wherein a first gap remains between the second semiconductor die and the first gap fill layer. The first semiconductor die and the second semiconductor die are bonded together. A first sealant layer is formed that fills an upper region of the first gap. A primary interconnect layer is then formed over the second semiconductor die. A second gap fill layer is formed on the primary interconnect layer. The second gap fill layer includes a second recess. A third semiconductor die is placed in the second recess, wherein a second gap remains between the third semiconductor die and the second gap fill layer. The primary interconnect layer and the third semiconductor die are bonded together. A second sealant layer is formed that fills an upper region of the second gap.

Also disclosed herein in still other embodiments are methods for forming a semiconductor package comprising a first semiconductor die, a second semiconductor die, and a third semiconductor die. The second semiconductor die and the third semiconductor die are bonded together to form an intermediate package. A gap fill layer is formed on the first semiconductor die, the gap fill layer including a recess. The intermediate package is placed in the recess such that the first semiconductor die is proximate the second semiconductor die. A gap remains between the intermediate package and the gap fill layer. The first semiconductor die and the second semiconductor die are bonded together. A sealant layer is formed that fills an upper region of the gap.

Also disclosed in various embodiments are semiconductor packages, comprising a first semiconductor die. A second semiconductor die is bonded to the first semiconductor die. A first gap fill layer surrounds the second semiconductor die, wherein a first gap remains around the second semiconductor die. A first sealant layer is present around the second semiconductor die that seals the first gap. A primary interconnect layer extends over the second semiconductor die, the sealant layer, and the gap fill layer. A third semiconductor die is bonded to the primary interconnect layer. A second gap fill layer surrounds the third semiconductor die, wherein a second gap remains around the third semiconductor die. A second sealant layer is present around the third semiconductor die that seals the second gap.

Also disclosed are semiconductor packages, comprising a first semiconductor die, a second semiconductor die bonded to the first semiconductor die; and a third semiconductor die bonded to the second semiconductor die. A gap fill layer surrounds the second semiconductor die and the third semiconductor die. A gap remains between the gap fill layer, the second semiconductor die, and the third semiconductor die. A sealant layer seals the gap.

Also disclosed are devices that include such semiconductor packages, as described above.

The methods and devices of the present disclosure are further illustrated in the following non-limiting working example, it being understood that this example is intended to be illustrative only and that the disclosure is not intended to be limited to the materials, conditions, process parameters and the like recited herein.

### EXAMPLES

Stress simulations were conducted using ANSYS software. A semiconductor package was made according to the present disclosure, having a gap between the gap fill layer and the top semiconductor die. The Von Mises stress at the top of the gap (adjacent the top semiconductor die, where the sealant layer is located) was 14 MPa. The Von Mises stress at the bottom of the gap was zero, due to the presence of air.

A semiconductor package was made in which the top semiconductor die was first attached to the bottom semiconductor die, the gap fill layer was applied across the top, and CMP was performed to remove the excess gap fill material upon the top die. The Von Mises stress at the top of the gap fill sidewall (adjacent the top semiconductor die) was 18.83 MPa. The Von Mises stress at the bottom of the gap fill sidewall was 171.95MPa.

Comparing the results, the semiconductor package made according to the present disclosure had much lower stress, which reduced cracking. The stress at the top of the gap was ˜25% lower, and the stress at the bottom of the gap was zero compared to 171.95 MPa.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a semiconductor package, comprising:
forming a gap fill layer on a first semiconductor die, the gap fill layer including a recess;
placing a second semiconductor die in the recess, wherein a gap remains between the second semiconductor die and the gap fill layer;
bonding the first semiconductor die and the second semiconductor die together; and
forming a sealant layer that fills an upper region of the gap.

2. The method of claim 1, wherein the sealant layer has a thickness of about one half of a thickness of the second semiconductor die or less.

3. The method of claim 1, wherein the second semiconductor die comprises a substrate, and the gap has a width that is at most about equal to a thickness of the second semiconductor die substrate.

4. The method of claim 3, wherein the second semiconductor die substrate has a thickness of about 5 micrometers to about 20 micrometers.

5. The method of claim 1, wherein the sealant layer is formed from an oxide.

6. The method of claim 1, wherein the sealant layer has an O/Si molar ratio of about 1 or less.

7. The method of claim 1, wherein the gap is filled with an inert gas.

8. The method of claim 1, wherein the gap fill layer is formed on a hybrid bonding layer of the first semiconductor die;
wherein the second semiconductor die is placed in the recess such that a hybrid bonding layer of the second semiconductor die contacts the hybrid bonding layer of the first semiconductor die; and
wherein the first semiconductor die and the second semiconductor die are bonded together by hybrid bonding.

9. The method of claim 1, further comprising forming a fusion bonding layer over the second semiconductor die;
attaching a carrier wafer to the fusion bonding layer; and
forming a backside interconnect layer on the first semiconductor die.

10. The method of claim 9, wherein the fusion bonding layer is formed from a dielectric material.

11. A semiconductor package, comprising:
a first semiconductor die;
a second semiconductor die bonded to the first semiconductor die;
a gap fill layer surrounding the second semiconductor die, wherein a gap remains around the second semiconductor die; and
a sealant layer around the second semiconductor die that seals the gap.

12. The package of claim 11, wherein the sealant layer has a thickness of about one half of a thickness of the second semiconductor die or less.

13. The package of claim 11, wherein the second semiconductor die comprises a substrate, and the gap has a width that is at most about equal to a thickness of the second semiconductor die substrate.

14. The package of claim 13, wherein the second semiconductor die substrate has a thickness of about 5 micrometers to about 20 micrometers.

15. The package of claim 11, further comprising a primary interconnect layer extending over the second semiconductor die, the sealant layer, and the gap fill layer.

16. The package of claim 11, wherein the first semiconductor die and the second semiconductor die each comprise a substrate, at least one interconnect layer, and a hybrid bonding layer.

17. The package of claim 11, wherein the gap is filled with an inert gas.

18. A method for forming a semiconductor package, comprising:
forming a first gap fill layer on a first semiconductor die, the first gap fill layer including a first recess;
placing a second semiconductor die in the first recess, wherein a first gap remains between the second semiconductor die and the first gap fill layer;
bonding the first semiconductor die and the second semiconductor die together;
forming a first sealant layer that fills an upper region of the first gap;
forming a primary interconnect layer over the second semiconductor die;
forming a second gap fill layer on the primary interconnect layer, the second gap fill layer including a second recess;
placing a third semiconductor die in the second recess, wherein a second gap remains between the third semiconductor die and the second gap fill layer;
bonding the primary interconnect layer and the third semiconductor die together; and
forming a second sealant layer that fills an upper region of the second gap.

19. The method of claim 18, further comprising forming a secondary interconnect layer over the third semiconductor die.

20. The method of claim 18, wherein the primary interconnect layer also covers the first gap fill layer, or wherein the secondary interconnect layer also covers the second gap fill layer.
